(19) United States
(12) Patent Application Publication
(10) Pub. No.: US 2025/0240001 A1
(43) Pub. Date: Jul. 24, 2025

(54) PULSE GENERATING SYSTEMS, PULSE GENERATING CIRCUITS, AND METHODS TO IMPROVE PERFORMANCE OF A PULSED POWER DRILLING SYSTEM

(71) Applicant: Halliburton Energy Services, Inc., Houston, TX (US)

(72) Inventor: Nagaraja K. PAI, Houston, TX (US)

(73) Assignee: Halliburton Energy Services, Inc., Houston, TX (US)

(21) Appl. No.: 18/418,178

(22) Filed: Jan. 19, 2024

(51) Int. Cl. H03K 4/08; E21B 7/15

(52) U.S. Cl. CPC H03K 4/08; E21B 7/15

(57) ABSTRACT

A pulse generating system includes a primary capacitor positioned along a primary side of a pulse generating circuit, and configured to store electrical energy, and a primary switch positioned along the primary side. The pulse generating system also includes a pulse transformer configured to step up voltage from the primary side to a secondary side of the pulse generating circuit; an output capacitor; and a secondary switch positioned in the secondary side, wherein the output capacitor is electrically coupled to the pulse transformer through the secondary switch.

### BACKGROUND

The present disclosure relates generally to pulse generating systems, pulse generating circuits, and methods to improve performance of a pulsed power drilling system. Pulsed power drills and pulsed power drilling systems repeatedly apply a high electric potential across electrodes of a pulsed power drill bit to generate electric arcs that fracture the surrounding formation. Due to the flow dynamics of the drilling fluids and the cuttings in combination with unpredictable arcing paths, not all electric arcs are productive or optimal. The sub-optimal arcs result in substantial energy getting trapped and dissipated in the components of pulsed power drilling systems, which may damage the pulsed power drilling systems.

### BRIEF DESCRIPTION OF THE DRAWINGS

Illustrative embodiments of the present disclosure are described in detail below with reference to the attached drawing figures, which are incorporated by reference herein, and wherein:

FIG. 1 is a schematic, side view of a well environment where a pulsed quality discriminator system is deployed;

FIG. 2 is a functional diagram of a pulsed quality discriminator system;

FIG. 3A is a circuit diagram of a pulse-generating circuit of a pulsed quality discriminator system;

FIG. 3B is a circuit diagram of another pulse-generating circuit of a pulsed quality discriminator system;

FIG. 4A is a line graph of a productive bit current pulse;

FIG. 4B is a line graph of a non-productive bit current pulse;

FIG. 5 is a block diagram of a pulsed quality discriminator system;

FIG. 6 is a flow chart of a process to improve performance of a pulsed power drilling system; and

FIG. 7 is a flow chart of a process to improve performance of a pulsed power drilling system.

The illustrated figures are only exemplary and are not intended to assert or imply any limitation with regard to the environment, architecture, design, or process in which different embodiments may be implemented.

### DETAILED DESCRIPTION

In the following detailed description of the illustrative embodiments, reference is made to the accompanying drawings that form a part hereof. These embodiments are described in sufficient detail to enable those skilled in the art to practice the invention, and it is understood that other embodiments may be utilized and that logical structural, mechanical, electrical, and chemical changes may be made without departing from the spirit or scope of the invention. To avoid detail not necessary to enable those skilled in the art to practice the embodiments described herein, the description may omit certain information known to those skilled in the art. The following detailed description is, therefore, not to be taken in a limiting sense, and the scope of the illustrative embodiments is defined only by the appended claims.

The present disclosure relates to pulse generating systems, pulse generating circuits, and methods to improve performance of a pulsed power drilling system. As referred to herein, a pulsed quality discriminator system is any system having hardware, software, firmware, and/or a combination thereof that is configured to determine the amount of energy transferred to a pulsed power drilling tool, and toggle different switches to charge different capacitors that provide voltage to the pulsed power drilling tool. In some embodiments, the pulsed power drilling system includes or is coupled to a pulse-generating circuit having a primary side and a secondary side, each coupled to a transformer to step-up the voltage of the capacitor(s) positioned along the secondary side to deliver sufficient voltage and energy to the pulsed power drill bit to perform successful cuts into the nearby formation.

The pulse-generating circuit includes a primary capacitor positioned along a primary side of the pulse-generating circuit, and configured to store electrical energy, and a primary switch positioned along the primary side. As referred to herein, primary capacitors and switches are capacitors and switches that are positioned along a primary side of the pulse-generating circuit, whereas secondary capacitors and switches are capacitors and switches positioned along a secondary side of the pulse-generating circuit. In some embodiments, the secondary capacitor is an output capacitor. In some embodiments, the primary side of the pulse-generating circuit includes additional capacitors and switches. In some embodiments, the primary side of the pulse-generating circuit also includes a power source configured to charge the primary capacitor. In some embodiments, the power source is an alternator with a rectifier and a multimode charger or a DC power supply with a multimode charger. In one or more of such embodiments, the multimode charger is programmable and configured to charge the primary capacitor in current or power control mode. In one or more of such embodiments, the primary side of the pulse-generating circuit also includes one or more inductors that are parallel to the power source, and electrically connected to the power source through one of the switches positioned on the primary side. In one or more of such embodiments, the power source is also in parallel with one or more capacitors positioned on the primary side, where the power source is electronically connected to the capacitors through one or more switches positioned on the primary side.

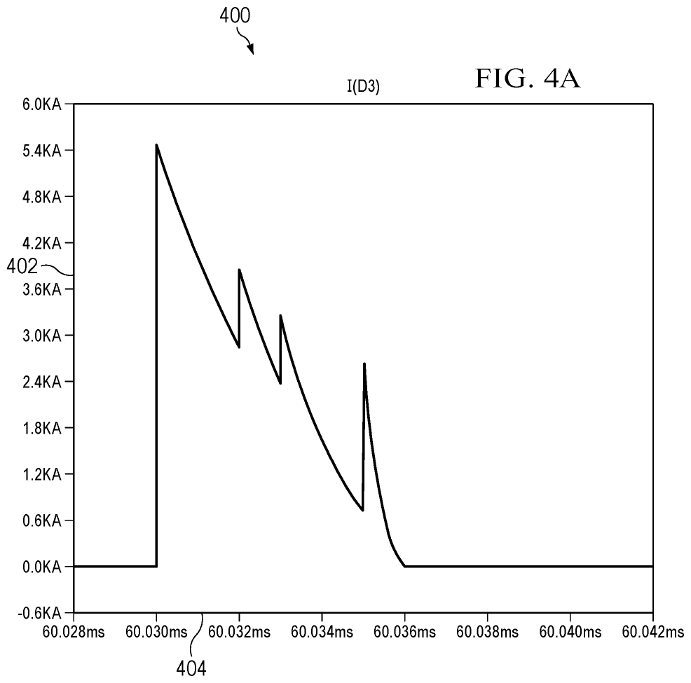

The pulse-generating circuit also includes a secondary capacitor positioned along the secondary side, and coupled to a drill bit, such as a pulse-powered drill bit, and a secondary switch positioned along the secondary side. In some embodiments, the secondary switch is in series with the secondary capacitor. The pulse-generating circuit also includes a pulse transformer configured to step up voltage from the primary side to the secondary side of the pulse-generating circuit. In some embodiments, the primary side of the pulse transformer is electrically connected to the primary capacitor through the primary switch, and the secondary side of the pulse transformer is electrically connected to the secondary capacitor through the secondary switch to step up voltage from the primary side to the secondary side of the pulse-generating circuit. In some embodiments, the secondary capacitor is in parallel with the second side of the pulse transformer and in parallel with the pulsed power drill bit. Additional descriptions of primary capacitors, secondary capacitors, and other circuit components of pulse-generating circuits and other circuits of the pulsed quality discriminator system are provided herein, and illustrated in at least FIGS. 3A and 3B.

A pulsed quality discriminator system (the processors of the pulsed quality discriminator system) is configured to determine energy transferred to a bit (pulsed power drill bit) of a pulsed power drilling tool. In some embodiments, the pulsed quality discriminator system monitors the pulsed power drill bit current and bit voltage across a pulsed power drill bit, and determines the energy transferred to bit electrodes of the pulsed power drill bit. In one or more of such embodiments, a threshold amount of energy is expected to be transferred from the pulsed power drill bit within a threshold period of time to generate sufficient energy to perform a successful cut into the formation. For example, at least 800 Joules of energy must be transferred from the pulsed power drill bit into a formation having a type specific material properties within five milliseconds in order to generate sufficient energy to cut into the formation. In one or more of such embodiments, where different types of formations require different amounts of threshold energy generated within different threshold periods of time, the pulsed quality discriminator system is configured to perform the operations described herein to determine whether the threshold amount of energy is generated within the threshold amount of time to successfully cut into the nearby formation. In some embodiments, the pulsed quality discriminator system determines the amount of energy transferred in real-time or near real-time, such that the operations described herein are performed within a single cutting cycle. In one or more of such embodiments, the pulsed quality discriminator system determines the amount of energy transferred in real-time or near real-time from the beginning of a cutting cycle to when the pulsed current reaches 100 Amps or another threshold Amperes.

The pulsed quality discriminator system determines not enough energy was transferred to the pulsed power drill bit if energy transferred is less than the energy threshold (e.g., 500 Joules, 800 Joules, greater than 800 Joules, or another threshold) within the threshold period of time (e.g., within five milliseconds). In some embodiments, the pulsed quality discriminator system, in response to a determination that the energy transferred to the pulsed power drill bit is not greater than an energy threshold within a threshold period of time, transfers (or initiates transfer of) energy from one or more secondary capacitors to one or more primary capacitors. In one or more of such embodiments, the pulsed quality discriminator system toggles one or more switches of the pulse-generating circuit to transfer energy stored in the secondary capacitors, inductors, and other components positioned along the secondary side of the pulse-generating circuit back to the primary capacitors. In that regard, the pulsed quality discriminator system, in response to a determination that the energy transferred to the pulsed power drill bit is not greater than an energy threshold within a threshold period of time, monitors voltage of a primary capacitor of the pulsed power drilling tool during a subsequent resonance cycle. Further, the pulsed quality discriminator system, in response to a determination that the voltage of the primary capacitor is above a voltage threshold, toggles (or requests a controller or another component of the pulsed quality discriminator system to toggle) a primary switch that is electrically connected to the primary capacitor to maintain energy captured by the primary capacitor. In some embodiments, the pulsed quality discriminator system periodically or dynamically determines a current through the primary capacitor, and determines that the voltage of the primary capacitor is above the voltage threshold in response to a determination that the current through the primary capacitor crosses 0, or another threshold current. In one or more of such embodiments, the pulsed quality discriminator system also blocks the current through the primary capacitor in response to the determination that the current through the primary capacitor crosses 0, or another threshold current.

The pulsed quality discriminator system requests or controls the primary capacitor (e.g., via a controller of the pulsed quality discriminator system) to charge from a stored voltage to an operating voltage during a subsequent cycle. In some embodiments, the pulsed quality discriminator system charges the primary capacitor from the stored voltage to 16 KV, or another threshold operating voltage. In one or more of such embodiments, pulsed quality discriminator system turns off an input charging system of the pulsed power drilling tool after charging the primary capacitor to 16 KV, or after charging the primary capacitor to another threshold operating voltage.

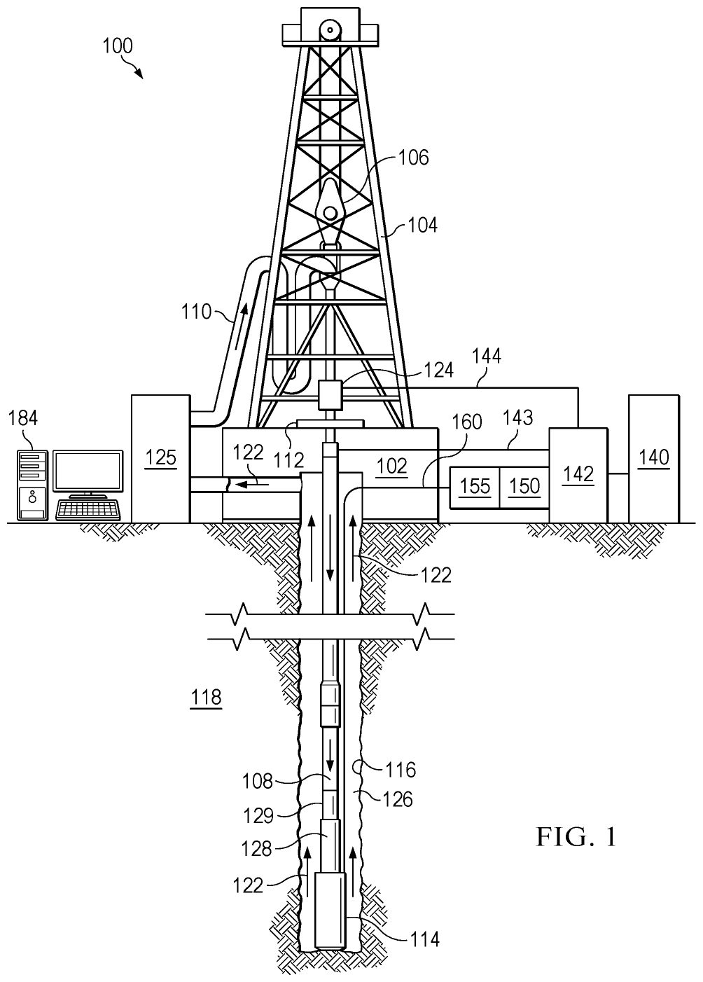

In some embodiments, the operations performed by the pulsed quality discriminator system are performed by processors of a pulse quality discriminator controller or another controller of the pulsed quality discriminator system. In some embodiments, the operations are performed by processors of a surface-based or cloud-based computing system. In that regard, in some embodiments, the pulsed quality discriminator system also includes surface-based computing systems such as system 184 of FIG. 1 and cloud-based computing systems that are configured to perform the operations described herein. In some embodiments, the pulsed quality discriminator system also includes additional capacitors, inductors, voltage sources, transformers, and other components of pulse-generating circuits and pulse-generating controllers. In some embodiments, the pulsed quality discriminator system also includes a bit of a pulsed power drilling tool, sensors of the pulsed power drilling tool, and other components of the pulsed power drilling tool configured to perform pulsed power drilling operations and to improve performance of pulsed power drilling operations. Additional descriptions of the foregoing pulse generating systems, pulse generating circuits, and methods to improve performance of a pulsed power drilling system are described in the paragraphs below and are illustrated in FIGS. 1-5.

Turning now to the figures, FIG. 1 is a schematic, side view of a well environment in which a pulsed quality discriminator system of a pulsed power drilling system 100 is deployed. More particularly, the pulsed quality discriminator system of FIG. 1 includes a surface-based computing system 184 and a downhole pulse quality controller 155, which are communicatively connected to each other via one or more telemetry means, and are configured to (individually and/or collectively) perform operations described herein to improve and optimize pulse power drilling operations. Although FIG. 1 shows land-based equipment, downhole tools incorporating teachings of the present disclosure may be satisfactorily used with equipment located on offshore platforms, drill ships, semi-submersibles, and drilling barges (not expressly shown). Additionally, while wellbore 116 is shown as being a generally vertical wellbore, wellbore 116 may be any orientation including generally horizontal, multilateral, or directional.

Pulsed power drilling system 100 includes drilling platform 102 that supports derrick 104 having traveling block 106 for raising and lowering drill string 108. Drill string 108 may be raised and lowered using a draw-works, such as a machine on the rig including a large diameter spool (not shown) of wire rope. The draw-works may be driven by a power source, such as an electric motor (not shown), or hydraulically to spool-in the wire rope to raise drill string 108. The draw-works may be able to spool-out the wire rope to lower drill string 108 under the force of gravity acting on drill string 108 within the wellbore. The draw-works may include a brake to control the lowering of drill string 108. The draw-works may include a crown block which, together with traveling block 106, form a block and tackle with several windings of the wire rope between them for mechanical advantage. Sensors may be mounted on or proximate to the draw-works spool to measure the rotation, from which changes in the depth of drill string 108 may be calculated. Time may also be measured and, together with the calculations of changes in depth, may enable the calculation of instantaneous and average rates of penetration (ROP). Pulsed power drilling system 100 may also include pump 125, which circulates drilling fluid 122 (also called “mud”) through a feed pipe to kelly 110, which in turn conveys drilling fluid 122 downhole through interior channels of drill string 108 and through one or more fluid flow ports in pulsed power drill bit 114. Drilling fluid 122 circulates back to the surface via annulus 126 formed between drill string 108 and the sidewalls of wellbore 116. Fractured portions of the formation (also called “cuttings”) are carried to the surface by drilling fluid 122 to remove those fractured portions from wellbore 116. Drilling fluid 122 and cuttings returning from downhole to the surface may flow over a shale shaker or another device that removes the cuttings from drilling fluid 122. The portion of drilling fluid 122 returned from downhole to the surface may be collected in surface tanks and may be tested by personnel or through automated fluid management systems, after which an adjustment to drilling fluid 122 may be initiated. For example, a person or automated system may examine, and subsequently initiate an adjustment to, properties of drilling fluid 122 that may have changed as a result of processes in wellbore 116. Sensors may be employed at the surface, e.g., at the shale shaker or along the flow lines through which drilling fluid 122 is returned to the surface, to examine the properties of the cuttings and drilling fluid 122 returned to the surface. Gas entrained in drilling fluid 122 or cuttings may be captured and analyzed by personnel or the volume and/or other characteristics of the entrained gas may be directly measured by sensors at the surface.

Pulsed power drilling system 100 may include valve 124 at the surface. The opening and closing of valve 124 may be controlled to create pressure pulses, sometimes referred to as mud pulses, in drilling fluid 122 that convey commands or other information to various downhole components. The pressure pulses, or mud pulses, may be sensed by a sensor at the BHA, e.g., a pressure sensor ported to the flow path of drilling fluid 122 through the BHA tubular elements. The resulting sensor signals may inform or be translated (e.g., by a processor) into commands used in controlling a pulsed drilling operation. The resulting sensor signals may be translated by various actuators into other types of control signals used to control a pulsed drilling operation.

Valve 124 may be positioned anywhere along the flow path of drilling fluid 122 from mud pump 125 to kelly 110. In one example, valve 124 may be in-line with the flow path and may, when activated, cause or relieve a restriction in the flow path to create mud pulses. In another example, valve 124 may be positioned to vent or bypass a portion of drilling fluid 122 or to make a change to a bypass from the main flow path of drilling fluid 122 to kelly 110 and drill string 108 to create mud pulses. In this example, the portion of drilling fluid 122 vented using valve 124 may then be returned by other pipes or tubular elements to mud tanks on the surface or to an inlet of mud pump 125. Valve 124 may include a solenoid or other mechanism for activation and may be controlled using an electrical signal input or a digital command.

Valve 124 may include a rotor and stator within the path of drilling fluid 122 to create periodic brief interruptions or restrictions in the flow of drilling fluid 122 as the turbine vanes cross the openings between the stator vanes. The rotor speed may be modulated (e.g., via electrical or mechanical braking) using an electrical control system, thus changing the periodicity or frequency of the interruptions and corresponding perturbations or pulses within drilling fluid 122.

Pulsed power drill bit 114 is attached to the distal end of drill string 108 and may be an electrocrushing drill bit or an electrohydraulic drill bit. Power may be supplied to drill bit 114 from components downhole, components at the surface and/or a combination of components downhole and at the surface. For example, generator 140 may generate electrical power and provide that power to power-conditioning unit 142. Power-conditioning unit 142 may then transmit electrical energy downhole via surface cable 143 and a sub-surface cable (not expressly shown in FIG. 1) contained within drill string 108 or attached to the outer wall of drill string 108. A pulse-generating (PG) circuit within BHA 128 may receive the electrical energy from power-conditioning unit 142 and may generate high-energy electrical pulses to drive drill bit 114. The high-energy electrical pulses may discharge through the rock formation and/or drilling fluid 122 and may provide information about the properties of the formation and/or drilling fluid 122. The pulse-generating circuit within BHA 128 may be located near drill bit 114. The pulse-generating circuit may include a power source input, including two input terminals, and a first capacitor coupled between the input terminals. The pulse-generating circuit may include a first inductor coupled between the input terminals with associated opening switch and a first capacitor coupled to the two ends of the inductor. The pulse-generating circuit may also include a switch, a transformer, and a second capacitor whose terminals are coupled to respective electrodes of drill bit 114. The switch may include a mechanical switch, a solid-state switch, a magnetic switch, a gas switch, or any other type of switch suitable to open and close the electrical path between the power source input and a first winding of the transformer. The transformer generates a current through a second winding when the switch is closed and current flows through first winding. The current through the second winding charges the second capacitor. As the voltage across the second capacitor increases, the voltage across the electrodes of the drill bit increases. In some embodiments, the pulse generating systems and circuits described herein include at least one of one or more primary windings and one or more primary switches and one or more primary capacitors. In some embodiments, the pulse generating systems and circuits described herein include at least one of one or more secondary switches and one or more secondary capacitors. In some embodiments, the transformer may be a segmented primary transforming including multiple primary windings and a single secondary winding. In another example, the transformer may be a magnetic core transformer. The pulse-generating circuit may also include a first inductor coupled between the input terminals with an associated opening switch and a second capacitor whose terminals are coupled to each end of the first inductor and to respective electrodes of drill bit 114. The first inductor may be an air core inductor or a magnetic core inductor and may generate the full voltage needed by the second capacitor for drilling. The inductor may be a segmented inductor including multiple windings with respective opening switches. Examples of pulse-generating circuits are illustrated in FIG. 3A and FIG. 3B.

The pulse-generating circuit within BHA 128 may be utilized to repeatedly apply a large electric potential across the electrodes of drill bit 114. For example, the applied electric potential may be in the range of 150 kv to 300 kv or higher. In this example, the lower bound on the applied electric potential may correspond to a lower bound on pulsed current of 500 amps. In another example, the lower bound on the applied electric potential may be 80 kv, with a lower bound on pulsed current of 500 amps. In yet another example, the lower bound on the applied electric potential may be 60 kv, again with a lower bound on pulsed current of 500 amps. Each application of electric potential is referred to as a pulse. The high-energy electrical pulses generated by the pulse-generating circuit may be referred to as pulse drilling signals. When the electric potential across the electrodes of drill bit 114 is increased enough during a pulse to generate a sufficiently high electric field, an electrical arc forms through rock formation 118 at the distal end of wellbore 116. The arc temporarily forms an electrical coupling between the electrodes of drill bit 114, allowing electric current to flow through the arc inside a portion of through rock formation 118 at the distal end of wellbore 116. The arc greatly increases the temperature and pressure of the portion of through rock formation 118 through which the arc flows and the surrounding formation and materials. The temperature and pressure are sufficiently high to break the rock into small bits referred to as cuttings. This fractured rock is removed, typically by drilling fluid 122, which moves the fractured rock away from the electrodes and uphole. The terms “uphole” and “downhole” may be used to describe the location of various components of pulsed power drilling system 100 relative to drill bit 114 or relative to the distal end of wellbore 116 shown in FIG. 1. For example, a first component described as uphole from a second component may be further away from drill bit 114 and/or the distal end of wellbore 116 than the second component. Similarly, a first component described as being downhole from a second component may be located closer to drill bit 114 and/or the distal end of wellbore 116 than the second component.

A sensor analysis system 150 may be positioned at the surface for use with pulsed power drilling system 100 as illustrated in FIG. 1, or at any other suitable location. Any suitable telemetry mechanism 160 may be used for communicating signals between downhole components and surface-based components. For example, telemetry mechanism 160 may be used for communicating signals from various acoustic, electrical or electromagnetic sensors at the surface or downhole to sensor analysis system 150 during a pulsed drilling operation. A pulse quality controller 155 may be positioned at the surface for use with pulsed power drilling system 100 as illustrated in FIG. 1, or at any other suitable location. As referred to herein, a pulse quality controller is any controller configured to toggle one or more switches of the pulse generation circuit and other circuits of the pulse quality discrimination system to charge different capacitors that provide voltage to drill bit 114. In the embodiment of FIG. 1, pulse quality controller 155 includes or is coupled to a pulse quality discriminator that is configured to perform different pulse discrimination operations described herein. In some embodiments, pulse quality controller 155 is a component of a pulse drilling controller. Any suitable telemetry system may be used for exchanging information by communicating acoustic, electrical or electromagnetic signals to or from pulse quality controller 155 during a pulsed drilling operation. More specifically, one or more input/output interfaces of pulse quality controller 155 may be configured for communication to or from various electrical, mechanical, or hydraulic components located downhole during a pulsed drilling operation. For example, pulse quality controller 155 may be coupled to telemetry mechanism 160, which may include an optical fiber that extends downhole in wellbore 116.

Pulse quality controller 155 may determine whether or when modifications should be made to the operating parameters of a pulsed drilling operation and may initiate the adjustment of CDCs that directly or indirectly affect any operating parameters that are to be modified without the need for those components to be removed from wellbore 116. For example, pulse quality controller 155 may initiate real-time adjustments to CDCs of a PPD system in response to changing conditions during a drilling operation. By making real-time adjustments, the number of times that all or a portion of drill string 108 is removed from wellbore 116 may be reduced and the ROP achieved during pulsed drilling operations may be improved.

Pulse quality controller 155 may be coupled to, or otherwise in communication with, sensor analysis system 150. Alternatively, the functionality of sensor analysis system 150 may be integrated within pulse quality controller 155, with pulse quality controller 155 acting as a master controller for pulsed drilling operations. Signal or informational inputs to pulse quality controller 155 may include measurements received from both downhole and surface sensors, or results of calculations made based on those measurements, indicating ROP, characteristics of cuttings, characteristics of drilling fluid 122 returning from downhole to the surface and/or entrained gas; downhole measurements of hole caliper or quality, vibration, or other wellbore characteristics; formation measurements; fluid pressure measurements; wellbore direction measurements; wellbore tortuosity or dogleg severity; and measurements of parameters within the pulsed power tool itself, such as power draw, voltages, currents, frequencies, or wave forms measured within the tool at various sensing points, some of which may be associated with one or more particular electronic components.

Inputs to pulse quality controller 155 may include modeled or otherwise calculated targets for one or more operating parameters of a pulsed drilling operation. Inputs to pulse quality controller 155 may include user specified target values for one or more operating parameters of a pulsed drilling operation.

Operating parameters of a pulsed drilling operation may be modified by adjusting one or more CDCs. The adjustments may be made using electrical components, such as by activating or deactivating solid state switches, using electromechanical components, e.g., by controlling relays, or using purely mechanical components, such as by mechanically toggling a device from one state to a second or subsequent state.

In the embodiment of FIG. 1, the pulsed quality discriminator system includes a downhole pulse quality controller 155 and a surface-based computing system 184. In some embodiments, pulse quality controller 155 and a similar computing system (not shown) are a single component that is deployed downhole, on the surface, and/or in the cloud, and configured to perform the operations described herein at real-time or near real-time. In some embodiments, the pulsed quality discriminator system does not include pulse quality controller 155, but is configured to request/control pulse quality controller 155 and other components of pulsed power drilling system 100 to perform operations described herein. In some embodiments, the pulsed quality discriminator system also includes one or more of pulsed power drill bit 114, the pulse-generating circuit, and other components of pulsed power drilling system 100 to perform operations described herein.

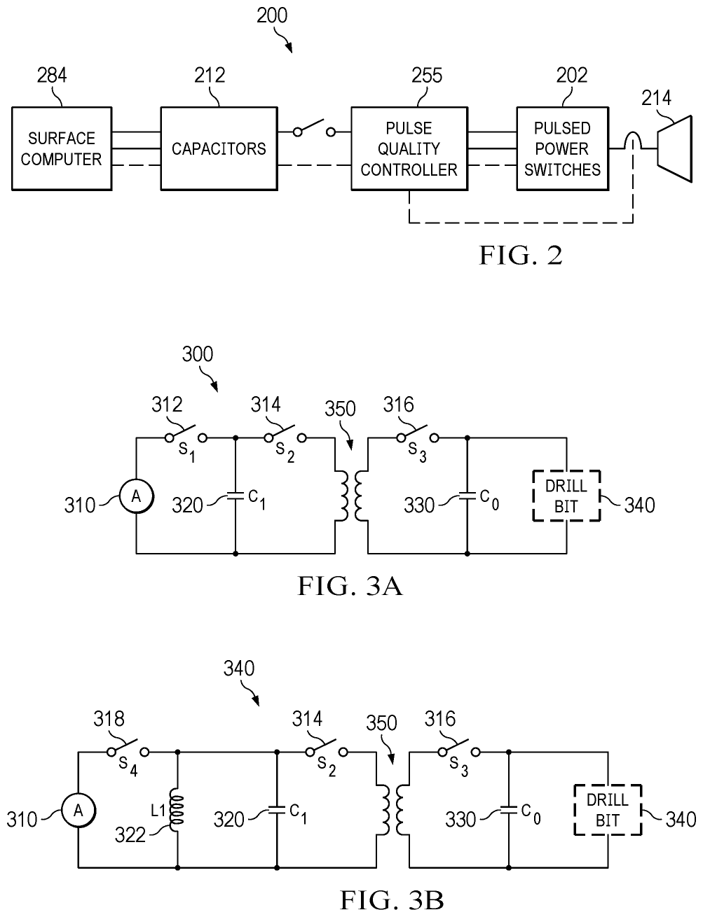

FIG. 2 is a functional diagram of a pulsed quality discriminator system 200. In the embodiment of FIG. 2, pulsed quality discriminator system 200 includes a surface-based computing system 284, capacitors 212, a pulse quality controller 255, switches 202, and a bit 214, which are connected to each other by power lines (solid lines) and control and feedback lines (dashed lines). In the embodiment of FIG. 2, surface-based computing system 284 is configured to perform operations described herein to determine the amount of energy transferred to bit 214, whether sufficient energy is generated to make successful cuts, and whether to toggle one or more switches in response to a determination that insufficient energy is generated to make successful cuts, all in real-time or near real-time. Surface-based computing system 284 is configured to transmit instructions on which switches to toggle to maintain energy captured by one or more capacitors, inductors, and/or other components of a pulse-generating circuit during subsequent cycles to a pulse quality controller 255 via telemetry. For example, surface-based computing system 284, in response to a determination that only 500 Joules of 800 Joules of energy required to make a successful cut is transferred, instructs pulse quality controller 255 to toggle one of switches 202 to transfer energy from a secondary capacitor of capacitors 212 back to a primary capacitor of capacitors 212. In another example, surface-based computing system 284, in response to a determination that more than 800 Joules of energy (or another threshold amount of energy) required to make a successful cut is transferred, instructs pulse quality controller 255 to toggle one of switches 202 to transfer energy from a secondary capacitor of capacitors 212 back to a primary capacitor of capacitors 212. In some embodiments, surface-based computing system 284 also provides the timing on when to toggle a switch of switches 202 (e.g., toggle off a primary switch when the current through the primary capacitor reaches 0 Amp).

Pulse quality controller 255 is configured to receive instructions from surface-based computing system 284 to toggle one or more of switches 202 to ensure a maximum amount of energy is captured by a primary capacitor of capacitors 212. After pulse quality controller 255 toggles one or more of switches 202 to permit one or more primary capacitors of capacitors 212 to recharge, pulsed quality discriminator system 200 tops off the primary capacitors to their operating voltage (e.g., 16 volts). In some embodiments, pulse quality controller 255 toggles one or more switches 202 to electrically connect one or more primary capacitors to an alternator, a power source, or to another component of pulse-generating circuit to permit the primary capacitors to top off to their operating voltage. In one or more of such embodiments, the voltage of the primary capacitors are held at their operating voltage (e.g., by pulse quality controller 255 or by another controller or component of pulsed quality discriminator system 200 until the subsequent pulse is generated for the next cutting cycle. In some embodiments, pulse quality controller 255 also includes one or more processors configured to perform operations performed by surface-based electronic system 284. In one or more of such embodiments, operations performed by surface-based electronic system 284 are instead performed by (the processors of) pulse quality controller 255. In some embodiments, capacitors 212 and switches 202 are components of a generating circuit. In some embodiments, pulsed quality discriminator system 200 includes additional components of pulsed power drilling system 100 of FIG. 1. In some embodiments, pulsed quality discriminator system 200 only includes an electronic system, such as surface-based electronic system 284, that is communicatively connected to other components, such as pulse quality controller 255, and configured to instruct pulse quality controller 255 and other components to perform operations described herein to perform and improve pulsed power drilling operations.

FIG. 3A is a circuit diagram of a pulse-generating circuit 300 of a pulsed quality discriminator system. In the embodiment of FIG. 3A, pulse-generating circuit 300 is configured to store electrical energy in a primary capacitor 320 positioned along a primary side of pulse-generating circuit 300. Primary capacitor 320 is charged by a power source 310 through a switch 312 positioned along the primary side of pulse-generating circuit 300. When the appropriate voltage has been reached on primary capacitor 320, that energy is switched by a second switch 314 also positioned along the primary side of pulse-generating circuit 300 into a pulse transformer 350 to step up the voltage and charge a secondary capacitor 330 that is positioned along a secondary side of pulse-generating circuit 300. The rising voltage on secondary capacitor 330, which is coupled to a drill bit 340, creates the electrical arc that fractures a nearby formation. In the embodiment of FIG. 3A, the primary side of pulse transformer 350 is electrically coupled to primary capacitor 320 through switch 314, and the secondary side of pulse transformer 350 is electrically coupled to secondary capacitor 330 through a secondary switch 316, which is toggled to disconnect the secondary side of pulse-generating circuit 300 once a threshold amount of energy returns from the secondary side to the primary side of pulse-generating circuit 300.

FIG. 3B is a circuit diagram of another pulse-generating circuit 340 of a pulsed quality discriminator system. In the embodiment of FIG. 3B, pulse-generating circuit 340 is configured to use an inductor for charging primary capacitor 320 positioned along a primary side of pulse-generating circuit 340. Primary capacitor 320 in turn is switched to transformer 350 to charge secondary capacitor 330. In the embodiment of FIG. 3B, current runs from the power source 310 through switch 318 through an inductor 322 to store energy in the magnetic field. When that current is interrupted by opening switch 318, a large voltage is created across inductor 322. In the embodiment of FIG. 3B, pulse-generating circuit 340 uses an opening switch 318 that first closes to connect inductor 322 to power source 310, or another power source, and then on command opens to interrupt that current flow, creating a voltage across inductor 322. In this example, opening switches such as switch 318 may need to be capable of high-voltage standoff. The voltage pulse from inductor 322 charges primary capacitor 320, which is then switched into transformer 350 via switch 314. The rising voltage on secondary capacitor 330, which is coupled to a drill bit 340, creates the electrical arc that fractures the rock. In the embodiment of FIG. 3B, pulse-generating circuit 340, inductor 322 and opening switch 318 may be used to step up the voltage output from power source 310. In the embodiment of FIG. 3B, pulse-generating circuit 340 uses inductive energy storage. Further, in the embodiment of FIG. 3B, the primary side of pulse transformer 350 is electrically coupled to primary capacitor 320 through switch 314, and the secondary side of pulse transformer 350 is electrically coupled to secondary capacitor 330 through a secondary switch 316, which is toggled to disconnect the secondary side of pulse-generating circuit 340 once a threshold amount of energy returns from the secondary side to the primary side of pulse-generating circuit 340.

In some embodiments, the pulsed quality discriminator systems described herein are configured to analyze electric arcs generated by a pulsed power drilling system, and categorize the generated arc based on characteristics of the corresponding current pulses. In one or more of such embodiments, the pulsed quality discriminator systems described herein are configured to categorize the electric arcs as one of a productive arc, an oil arc, a surface arc, or a resistive arc based on the characteristics of the corresponding current pulses. In some embodiments, an oil arc is an electrical discharge from the drill bit center electrode to the peripheral electrode through the oil based drilling fluid. In some embodiments, a resistive arc occurs when a portion of this electrical discharge may pass though the formation without creating any pressure wave. In some embodiments, a surface arc occurs when most of the electrical discharge is on the surface of the formation. In some embodiments, oil arc, resistivity arc, and surface arc are non-productive arcs.

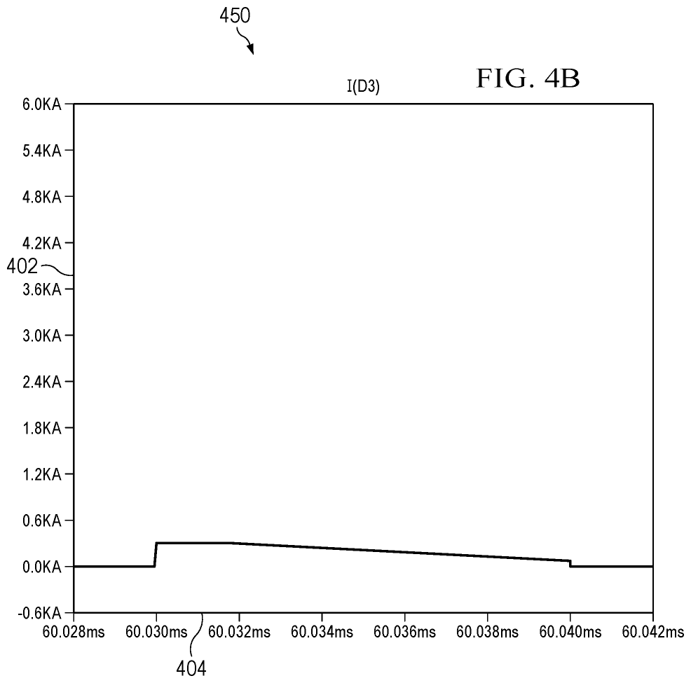

FIGS. 4A and 4B are line graphs 400 and 450 of productive and non-productive bit current pulses, respectively. FIG. 4A, is a line graph 400 of a productive bit current pulse, whereas FIG. 4B is a line graph 450 of a non-productive bit current pulse. In the embodiments of FIGS. 4A and 4B, axis 402 represents the amplitude of the pulsed current and axis 404 represents time. In the embodiment of FIG. 4A, the pulsed current reached a threshold current within a threshold period of time, which is indicative that a productive arc was generated. To the contrary, the pulsed current of FIG. 4B did not reach the threshold current within the threshold period of time, which is indicative that a non-productive arc (e.g., an oil arc, a surface arc, or a resistive arc) was generated.

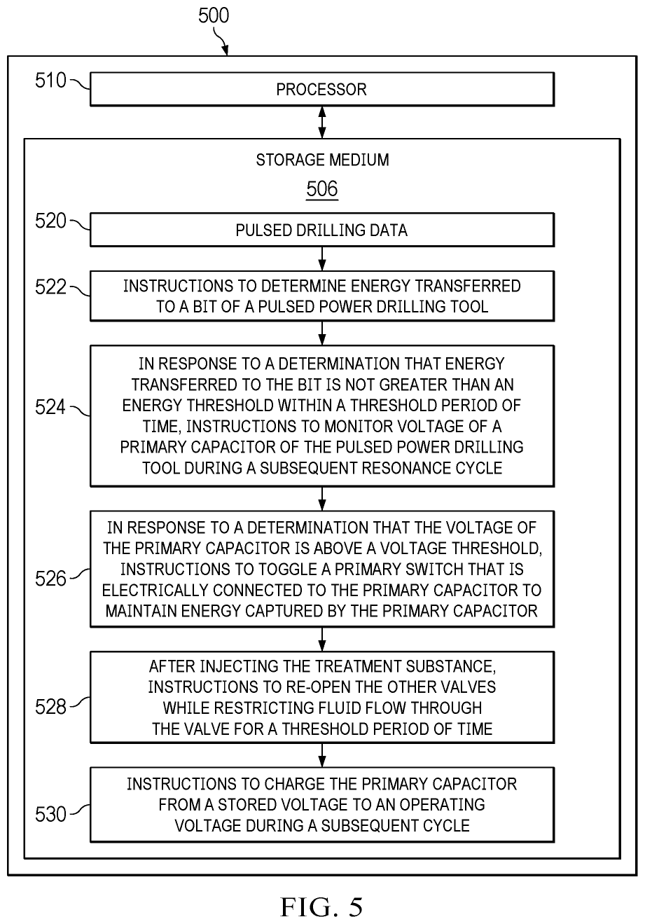

FIG. 5 is a block diagram of a pulsed quality discriminator system 500. Pulsed quality discriminator system 500 includes a storage medium 506 and a processor 510. The storage medium 506 may be formed from data storage components such as, but not limited to, read-only memory (ROM) Fapom4me4!, random access memory (RAM), flash memory, magnetic hard drives, solid state hard drives, CD-ROM drives, DVD drives, floppy disk drives, as well as other types of data storage components and devices. In some embodiments, the storage medium 506 includes multiple data storage devices. In further embodiments, the multiple data storage devices may be physically stored at different locations. In one of such embodiments, the data storage devices are components of a server station, such as a cloud server. Data indicative of pulsed drilling operations including the voltage and current across one or more capacitors, inductors, and other components of a pulsed power drilling system such as pulsed power drilling system 100 of FIG. 1 (collectively “pulsed drilling data”) are stored at a first location 520 of storage medium 506. Further, instructions to determine energy transferred to a bit of a pulsed power drilling tool are stored at a second location 522 of storage medium 506. Further, in response to a determination that the energy transferred to the bit is not greater than an energy threshold within a threshold period of time, instructions to monitor voltage of a primary capacitor of the pulsed power drilling tool during a subsequent resonance cycle are stored at a third location 524 of storage medium 506. Further, in response to a determination that the voltage of the primary capacitor is above a voltage threshold, instructions to toggle a primary switch that is electrically connected to the primary capacitor to maintain energy captured by the primary capacitor are stored at a fourth location 526 of storage medium 506. Further, instructions to charge the primary capacitor from a stored voltage to an operating voltage during a subsequent cycle are stored at a fifth location 320 of storage medium 506.

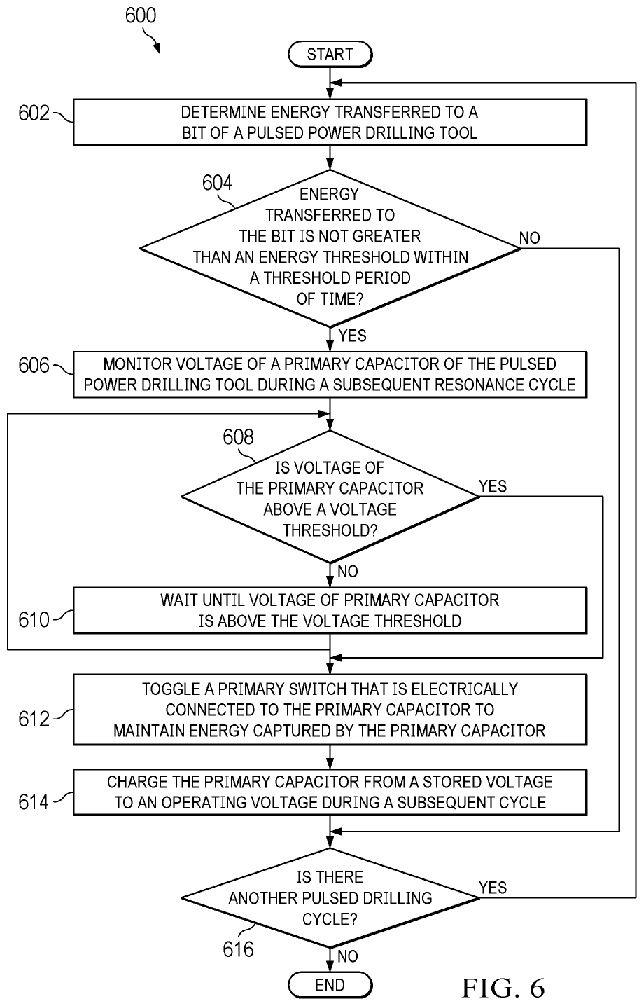

FIG. 6 is a flow chart of a process 600 to improve performance of a pulsed power drilling system. Although the operations in process 600 are shown in a particular sequence, certain operations may be performed in different sequences or at the same time where feasible.

At block 602, a pulsed quality discriminator system, such as pulsed quality discriminator system 200 of FIG. 2 is configured to determine the amount of energy transferred to a bit of a pulsed power drilling tool. At block 604, a determination of whether energy transferred to the bit is not greater than an energy threshold within a threshold period of time is made. If the energy transferred to the bit is greater than the energy threshold within the threshold period of time (e.g., greater than 800 Joules within five milliseconds), then the foregoing is indicative of a successful cut, and process 600 proceeds to block 616. Alternatively, if the energy transferred to the bit is not greater than the energy threshold within the threshold period of time, then process 600 proceeds to block 606. At block 606 the pulsed quality discriminator system monitors the voltage of a primary capacitor of the pulsed power drilling tool during a subsequent resonance cycle.

At block 608, the pulsed quality discriminator system determines whether voltage of the primary capacitor is above a voltage threshold. Process 600 proceeds to block 610 if the voltage of the primary capacitor is not above the voltage threshold. At block 610, the pulsed quality discriminator system waits/holds until the voltage of the primary capacitor is above the voltage threshold, and process 600 returns to block 608. Alternatively, at block 608, the pulsed quality discriminator system in response to a determination that the voltage of the primary capacitor is above the voltage threshold, proceeds to block 612, and toggles a primary switch that is electrically connected to the primary capacitor to maintain energy captured by the primary capacitor. Process 600 then proceeds to block 614. At block 614, the pulsed quality discriminator system charges the primary capacitor from a stored voltage to an operating voltage during a subsequent cycle. Process 600 then proceeds to block 616, and the pulsed quality discriminator system determines if there is another pulsed drilling cycle. Process 600 returns to block 602 and operations of process 600 are repeated during subsequent pulsed drilling cycles. Alternatively, process 600 ends if the pulsed drilling operations are complete.

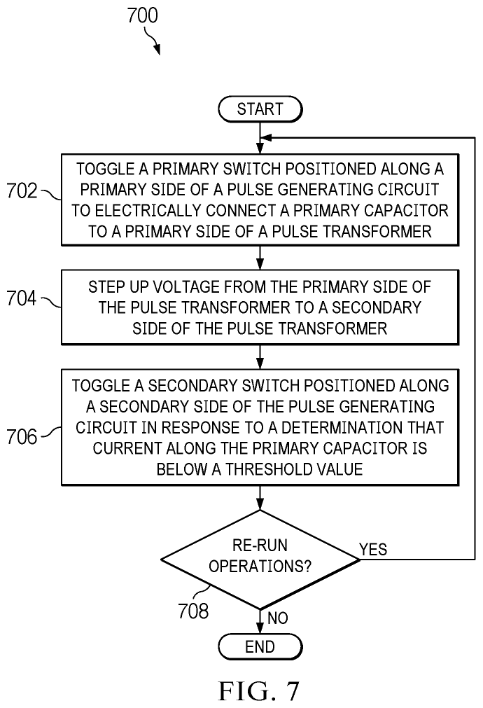

FIG. 7 is a flow chart of another process 700 to improve performance of a pulsed power drilling system. Although the operations in process 700 are shown in a particular sequence, certain operations may be performed in different sequences or at the same time where feasible.

At block 702, the pulsed quality discriminator system toggles a primary switch positioned along a primary side of a pulse-generating circuit to electrically connect a primary capacitor to a primary side of a pulse transformer. Process 700 then proceeds to block 704. At block 704, the pulsed quality discriminator system steps up voltage from the primary side of the pulse transformer to a secondary side of the pulse transformer. Process 700 then proceeds to block 706. At block 706, and in response to a determination that current along the primary capacitor is below a threshold value, the pulsed quality discriminator system toggles a secondary switch positioned along a secondary side of the pulse-generating circuit. Process 700 then proceeds to block 708, and the pulsed quality discriminator system determines if there is another pulsed drilling cycle. Process 708 returns to block 702 and operations of process 700 are repeated during subsequent pulsed drilling cycles. Alternatively, process 700 ends if the pulsed drilling operations are complete.

The above-disclosed embodiments have been presented for purposes of illustration and to enable one of ordinary skill in the art to practice the disclosure, but the disclosure is not intended to be exhaustive or limited to the forms disclosed. Many insubstantial modifications and variations will be apparent to those of ordinary skill in the art without departing from the scope and spirit of the disclosure. For instance, although the flowcharts depict a serial process, some of the steps/processes may be performed in parallel or out of sequence, or combined into a single step/process. The scope of the claims is intended to broadly cover the disclosed embodiments and any such modification. Further, the following clauses represent additional embodiments of the disclosure and should be considered within the scope of the disclosure.

Clause 1, a pulse generating system, comprising: a primary capacitor positioned along a primary side of a pulse generating circuit, and configured to store electrical energy; a primary switch positioned along the primary side; a pulse transformer configured to step up voltage from the primary side to a secondary side of the pulse generating circuit; an output capacitor; and a secondary switch positioned in the secondary side, wherein the output capacitor is electrically coupled to the pulse transformer through the secondary switch.

Clause 2, the pulse generating system of clause 1, wherein the output capacitor positioned in the secondary side, and coupled to a drill bit.

Clause 3, the pulse generating system of clauses 1 or 2, wherein the secondary switch is in series with the output capacitor.

Clause 4, the pulse generating system of any of clauses 1-3, wherein a primary side of the pulse transformer is electrically coupled to the primary capacitor through the primary switch, and wherein a secondary side of the pulse transformer is electrically coupled to the secondary capacitor through the secondary switch.

Clause 5, the pulse generating system of any of clauses 1-4, further comprising a second primary switch positioned along the primary side.

Clause 6, the pulse generating system of clause 5, further comprising of a power source configured to charge the primary capacitor through the second primary switch.

Clause 7, the pulse generating system of clause 6, wherein the primary capacitor is in parallel with the power source, and wherein the primary capacitor is electrically coupled to the power source through the second primary switch.

Clause 8, the pulse generating system of clauses 6 or 7, further comprising an inductor in series with the power source and electrically coupled to the power source through the second primary switch, wherein the primary capacitor is electrically coupled to a primary side of the pulse transformer through a primary switch, and wherein the secondary capacitor is in parallel with a secondary side of the pulse transformer and in parallel with a pulsed-power drill bit.

Clause 9, the pulse generating system of any of clauses 1-8, further comprising at least one of one or more primary windings and one or more primary switches and one or more primary capacitors.

Clause 10, the pulse generating system of any of clauses 1-9, further comprising at least one of one or more secondary windings and one or more secondary switches and one or more secondary capacitors.

Clause 11, a pulse generating circuit, comprising: a primary capacitor positioned along a primary side of the pulse generating circuit, and configured to store electrical energy; a primary switch positioned along the primary side; a pulse transformer configured to step up voltage from the primary side to a secondary side of the pulse generating circuit; an output capacitor positioned along the secondary side, and coupled to a drill bit; and a secondary switch positioned along the secondary side, wherein the output capacitor is electrically coupled to the pulse transformer through the secondary switch.

Clause 12, the pulse generating circuit of clause 11, wherein the secondary switch is in series with the output capacitor.

Clause 13, the pulse generating circuit of clauses 11-12, wherein a primary side of the pulse transformer is electrically coupled to the primary capacitor through the primary switch, and wherein a secondary side of the pulse transformer is electrically coupled to the secondary capacitor through the secondary switch.

Clause 14, the pulse generating circuit of any of clauses 11-13, further comprising a second primary switch positioned along the primary side.

Clause 15, the pulse generating circuit of clause 14, further comprising an alternator configured to charge the primary capacitor through the second primary switch, wherein the primary capacitor is in parallel with the alternator, and wherein the primary capacitor is electrically coupled to the alternator through the second primary switch.

Clause 16, the pulse generating circuit of clause 15, further comprising an inductor in parallel with the alternator and electrically coupled to the alternator through the second primary switch, wherein the primary capacitor is electrically coupled to a primary side of the pulse transformer through a primary switch, and wherein the output capacitor is in parallel with a secondary side of the pulse transformer and in parallel with a pulsed-power drill bit.

Clause 17, the pulse generating circuit of any of clauses 11-16, further comprising at least one of one or more primary windings and one or more primary switches and one or more primary capacitors.

Clause 18, the pulse generating circuit of any of clauses 11-17, further comprising at least one of one or more secondary windings and one or more secondary switches and one or more secondary capacitors.

Clause 19, a method to improve performance of a pulsed power drilling system, comprising: toggling a primary switch positioned along a primary side of a pulse generating circuit to electrically connect a primary capacitor to a primary side of a pulse transformer; stepping up voltage from the primary side of the pulse transformer to a secondary side of the pulse transformer; and in response to a determination that current along the primary capacitor is below a threshold value, toggling a secondary switch positioned along a secondary side of the pulse generating circuit, wherein the secondary switch electrically couples the secondary side of the pulse transformer to the output capacitor.

Clause 20, the method of clause 19, further comprising toggling the primary switch to conserve energy on the primary side, wherein the primary switch and the secondary switch are toggled at different times.

As used herein, the singular forms “a,” “an,” and “the” are intended to include the plural forms as well, unless the context clearly indicates otherwise. It will be further understood that the terms “comprise” and/or “comprising,” when used in this specification and/or in the claims, specify the presence of stated features, steps, operations, elements, and/or components, but do not preclude the presence or addition of one or more other features, steps, operations, elements, components, and/or groups thereof. In addition, the steps and components described in the above embodiments and figures are merely illustrative and do not imply that any particular step or component is a requirement of a claimed embodiment.

What is claimed is:

1. A pulse generating system, comprising:
a primary capacitor positioned along a primary side of a pulse generating circuit, and configured to store electrical energy;
a primary switch positioned along the primary side;
a pulse transformer configured to step up voltage from the primary side to a secondary side of the pulse generating circuit;
an output capacitor; and
a secondary switch positioned in the secondary side, wherein the output capacitor is electrically coupled to the pulse transformer through the secondary switch.

2. The pulse generating system of claim 1, wherein the output capacitor positioned in the secondary side, and coupled to a drill bit.

3. The pulse generating system of claim 1, wherein the secondary switch is in series with the output capacitor.

4. The pulse generating system of claim 1, wherein a primary side of the pulse transformer is electrically coupled to the primary capacitor through the primary switch, and wherein a secondary side of the pulse transformer is electrically coupled to the secondary capacitor through the secondary switch.

5. The pulse generating system of claim 1, further comprising a second primary switch positioned along the primary side.

6. The pulse generating system of claim 5, further comprising of a power source configured to charge the primary capacitor through the second primary switch.

7. The pulse generating system of claim 6, wherein the primary capacitor is in parallel with the power source, and wherein the primary capacitor is electrically coupled to the power source through the second primary switch.

8. The pulse generating system of claim 6, further comprising an inductor in series with the power source and electrically coupled to the power source through the second primary switch, wherein the primary capacitor is electrically coupled to a primary side of the pulse transformer through a primary switch, and wherein the secondary capacitor is in parallel with a secondary side of the pulse transformer and in parallel with a pulsed-power drill bit.

9. The pulse generating system of claim 1, further comprising at least one of one or more primary windings and one or more primary switches and one or more primary capacitors.

10. The pulse generating system of claim 1, further comprising at least one of one or more secondary windings and one or more secondary switches and one or more secondary capacitors.

11. A pulse generating circuit, comprising:
a primary capacitor positioned along a primary side of the pulse generating circuit, and configured to store electrical energy;
a primary switch positioned along the primary side;
a pulse transformer configured to step up voltage from the primary side to a secondary side of the pulse generating circuit;
an output capacitor positioned along the secondary side, and coupled to a drill bit; and
a secondary switch positioned along the secondary side, wherein the output capacitor is electrically coupled to the pulse transformer through the secondary switch.

12. The pulse generating circuit of claim 11, wherein the secondary switch is in series with the output capacitor.

13. The pulse generating circuit of claim 11, wherein a primary side of the pulse transformer is electrically coupled to the primary capacitor through the primary switch, and wherein a secondary side of the pulse transformer is electrically coupled to the secondary capacitor through the secondary switch.

14. The pulse generating circuit of claim 11, further comprising a second primary switch positioned along the primary side.

15. The pulse generating circuit of claim 14, further comprising an alternator configured to charge the primary capacitor through the second primary switch, wherein the primary capacitor is in parallel with the alternator, and wherein the primary capacitor is electrically coupled to the alternator through the second primary switch.

16. The pulse generating circuit of claim 15, further comprising an inductor in parallel with the alternator and electrically coupled to the alternator through the second primary switch, wherein the primary capacitor is electrically coupled to a primary side of the pulse transformer through a primary switch, and wherein the output capacitor is in parallel with a secondary side of the pulse transformer and in parallel with a pulsed-power drill bit.

17. The pulse generating circuit of claim 11, further comprising at least one of one or more primary windings and one or more primary switches and one or more primary capacitors.

18. The pulse generating circuit of claim 11, further comprising at least one of one or more secondary windings and one or more secondary switches and one or more secondary capacitors.

19. A method to improve performance of a pulsed power drilling system, comprising:
toggling a primary switch positioned along a primary side of a pulse generating circuit to electrically connect a primary capacitor to a primary side of a pulse transformer;
stepping up voltage from the primary side of the pulse transformer to a secondary side of the pulse transformer; and
in response to a determination that current along the primary capacitor is below a threshold value, toggling a secondary switch positioned along a secondary side of the pulse generating circuit, wherein the secondary switch electrically couples the secondary side of the pulse transformer to the output capacitor.

20. The method of claim 19, further comprising toggling the primary switch to conserve energy on the primary side, wherein the primary switch and the secondary switch are toggled at different times.
